(19) United States
(12) Patent Application Publication
(10) Pub. No.: US 2007/0151862 A1
(43) Pub. Date: Jul. 5, 2007

(54) POST DEPOSITION TREATMENTS OF ELECTRODEPOSITED CUINSE2-BASED THIN FILMS

(76) Inventors: Kevin D. Dobson, Newark, DE (US); M. Estela Calixto, Mexico City (MX); Brian E. McCandless, Elkton, MD (US); Robert W. Birkmire, Newark, DE (US)

Correspondence Address: KIRKPATRICK & LOCKHART PRESTON GATES ELLIS LLP, 1900 MAIN STREET, SUITE 600, IRVINE, CA, 92614-7319, US

(21) Appl. No.: 11/611,717

(22) Filed: Dec. 15, 2006

Related U.S. Application Data
(63) Continuation-in-part of application No. PCT/US06/38867, filed on Oct. 3, 2006.
(60) Provisional application No. 60/750,759, filed on Dec. 15, 2005.
(60) Provisional application No. 60/723,505, filed on Oct. 3, 2005.

(51) Int. Cl. C25D 5/48; C25D 3/58; H01L 31/00

(52) U.S. Cl. 205/220; 205/239; 136/262; 136/264; 136/265

(57) ABSTRACT

Single bath electrodeposition of polycrystalline Cu(In,Ga)Se₂ thin films for photovoltaic applications is disclosed. Specifically, Cu(In,Ga)Se₂ was deposited onto Mo electrodes from low concentration buffered (pH 2.5) aqueous baths containing CuCl₂, InCl₃, GaCl₃ and H₂SeO₃. Moreover, buffered aqueous baths are disclosed wherein Se⁴⁺/Cu²⁺ concentration ratios were controlled to optimize Se and Cu levels, while In³⁺ concentration was adjusted to control deposited In and Ga. Further disclosed are pre- and post-deposition processing methods resulting in smooth, compact, crack-free films of near stoichiometric values. Post deposition heat treatments on electrodeposited CuInSe₂-based films in selenium and sulfur containing atmosphere are described. CuInSe₂-based films from a single bath deposited onto Mo electrodes from low concentration aqueous baths. Heat treatment of electrodeposited Cu(In,Ga)Se₂ in H₂Se producing an O-free crystalline film and annealing in Se-vapor producing crystalline CuInSe₂ without loss of Ga or O).

### CROSS REFERENCE TO RELATED APPLICATIONS

This application is a continuation-in-part of International Patent Application No. PCT/US2006/38867 filed Oct. 3, 2006, and whose entire contents are hereby incorporated by reference, which claims the benefit of the U.S. Provisional Application No. 60/723,505, filed Oct. 3, 2005, and whose entire contents are hereby incorporated by reference. This application further claims the benefit of U.S. Provisional Application No. 60/750,759 filed Dec. 15, 2005 and whose entire contents are hereby incorporated by reference.

### FIELD OF THE INVENTION

The present invention relates to improved photovoltaic devices and methods for their manufacture. Specifically, the present invention includes improved photovoltaic solar cells made using single, buffered bath electrodeposition of copper, indium, gallium and selenium.

### BACKGROUND OF THE INVENTION

Polycrystalline Cu(In,Ga)Se₂ has exhibited very promising performance for thin film photovoltaic (PV) applications, now exceeding 19% conversion efficiencies at the laboratory scale. The best quality devices, hitherto, have been processed using high vacuum based techniques. However, there is an interest in developing deposition techniques that avoid the use of high vacuum, especially when considering scale-up to industrial processing levels. Electrodeposition offers a number of advantages over high-vacuum deposition techniques, requiring only off-the-shelf, low cost equipment and allows deposition over large areas at low temperature conditions, good control of film thickness, and potentially high utilization of bath species. The high absorption coefficient of Cu(In,Ga)Se₂ (˜10⁵ cm⁻¹) allows thin films, <2 μm, to be applied to PV devices. Electrodeposited CdTe PV devices have been successfully processed, reaching near commercial performance.

A number of groups have reported electrodeposition-based processing of CuInSe₂ and Cu(In,Ga)Se₂ films, employing a number of approaches; sequential deposition of individual metal films, deposition of various precursors, and single-step deposition, where all elements are deposited simultaneously. Single deposition processes are appealing in order to simplify device manufacture. The successful deposition of CuInSe₂ from a single electrochemical bath onto a range of different substrate types has been previously reported, and a few groups have attempted to describe bath chemistry and mechanisms of film growth. As-deposited films are generally of low crystallinity and a post deposition anneal, often in a selenium-containing atmosphere, is required to drive formation reactions and film recrystallization while maintaining or controlling film chemistry. Other approaches to Cu(In,Ga)Se₂ processing, including sputtering of individual metal films followed by selenization, are hindered by the requirement of high vacuum equipment, high temperature deposition and control of film composition profiles.

Despite the number of reports of electrodeposited CuInSe₂, only a few studies of electrodeposition of Cu(In,Ga)Se₂ have appeared in the literature. These have included multi-deposition approaches, sometimes with vacuum techniques also complementing electrodeposition. Zank et al. (Thin Solid Films, 286:259, 1996) described the formation of Cu(In,Ga)Se₂ films via co-electrodeposition of In and Ga from aqueous cyanide solutions onto sputtered Cu—Ga films. Friedfeld et al. (Adv Mater Optics Electronics, 8:1, 1998) reported a 2-step Cu(In,Ga)Se₂ electrodeposition, first depositing a Cu—Ga alloy at high pH, followed by electrodeposition of CuInSe₂. Kampmann et al. (Mat Res Soc Symp, 763:323. 2003) reported growth of CuInSe₂ and Cu(In,Ga)Se₂ on Mo foil and stainless steel by sequential electrodeposition of Cu, In, and Ga, followed by Se evaporation. Bhattacharya et al. have reported deposition of precursor layers for Cu(In,Ga)Se₂ devices using dc (Appl Phys Lett, 75:1431,1999; Sol. Energy Mater Sol Cells, 63:367, 2000; Thin Solid Films, 361:396, 2000; Sol Energy Mater Sol Cells, 59:125, 1999; Sol Energy Mater Sol Cells, 70:345, 2001) and pulse electrodeposition (Sol Energy Mater Sol Cells, 55:83, 1998). The resultant films, however, contained very low levels of Ga and, to allow device processing, films were supplemented by physical vapor deposition (PVD) of Cu, In, Ga and Se by up to 50% of the total film thickness. Buffering the baths was found to improve the composition of deposited films, but further PVD of In and Se at 500° C., adding up to 10% of the film thickness, was still required for device processing. Reports of single-step electrodeposition of thin Cu(In,Ga)Se₂ films have included Matsuoka et al. (Jpn J Appl Phys, 33:6105, 1994) who described processing of devices from CuGaₓIn₁₋ₓSe₂ films deposited on SnO₂-coated glass. Shanker and Garg (Solid State Phenomena, 55:117, 1997) reported the single-step electrodeposition of a range of Cu(In,Ga)Se₂ alloys, of band-gaps between 1.20 to 1.65 eV, from a high pH bath. Kampmann et al. (Thin Solid Films, 361:309, 2000) reported large area, 80 cm², electrodeposition of Cu(In,Ga)Se2 from single baths onto Mo and ITO/In₂Se₃ substrates. Delsol et al. (Sol Energy Mater Sol Cells, 77:331, 2003) have reported processing of Cu(In,Ga)Se₂ films from a one-step electrodeposition process, however, the presence of Ga within the deposited films could not be confirmed from x-ray photoelectron spectroscopy analysis, suggesting that Ga was only present in proportions of <0.5%. Zhang et al. (Sol Energy Mater Sol Cells, 80:483, 2003) have recently reported the single-step deposition of Cu(In,Ga)Se₂ films containing as high as 23% Ga. Bouabid et al. (J Phys IV France, 123:53, 2005) and Fahoume et al. (J Phys IV France, 123:75, 2005) have also both recently reported the one step electrodeposition of CuIn₁₋ₓGaₓSe₂ thin films. Calixto et al. (Sol Energy Mater Sol Cells, 59:75, 1999) reported single-step electrodeposition of Cu(In,Ga)Se₂ containing 1.84% Ga, highlighting that films of good structural, morphological and optoelectronic properties can be obtained with careful control of bath conditions. Fernandez and Bhattacharya (Thin Solid Films, 474:10, 2005) reported the effects of solution concentration on composition and morphology of single bath electrodeposited Cu(In,Ga)Se₂ films. Electrodeposition of CuInSe₂ and Cu(In,Ga)Se₂ from single baths, with close to stoichiometric composition, processing devices of 6.7% and 4.6% conversion efficiencies, respectively, have been reported. Furthermore cyclic voltammetry (CV) has been applied to understand the mechanism of Cu(In,Ga)Se₂ electrodeposition. Guimard et al. (Mat Res Soc Symp Proc, 763:281, 2003) have recently reported the development of electrodeposited Cu(In,Ga)Se₂-based devices, without extra vacuum deposition processing, exceeding 10% efficiency, though no details regarding film deposition were presented. Lincot et al. (Sol Energy, 77:725, 2004) have recently reviewed aspects of the electrodeposition of chalcopyrites for photovoltaic application.

The dearth of reports regarding electrodeposition of Cu(In,Ga)Se₂, compared to CuInSe₂, may be due to a number of possible difficulties, including; controlling the electrochemistry of four species of wide-ranging potentials; controlling deposited film composition and growth chemistry; avoiding the co-deposition of oxides and other secondary phases; and the instability of In³⁺ and Ga³⁺ ions in aqueous conditions at near neutral and alkaline pH. In particular, difficulty in incorporating significant Ga levels into the deposited films, from a single-deposition has hindered development of electrodeposited Cu(In,Ga)Se₂. Similar difficulties have been previously discussed for the electrodeposition of device quality GaAs. Therefore, there remains a need for improved methods for making high efficiency thin film photovoltaic devices based on electrodeposited Cu(In,Ga)Se₂.

### SUMMARY OF THE INVENTION

The present invention provides methods for the electrodeposition of Cu(In,Ga)Se₂ films from single buffered aqueous baths and photovoltaic devices derived therefrom. In one embodiment deposition conditions, including bath concentrations, deposition potential and the nature of the electrode surface, resulted in production of as-deposited films with smooth morphology and good control of composition.

In another embodiment of the present invention Cu(In,Ga)Se₂ films are produced from a vacuum-free, single-step electrodeposition process wherein the buffered bath and careful control of concentrations allowed the growth of films containing up to 8% Ga.

In yet another embodiment of the present invention methods are provided for controlling thin film composition by adjusting bath concentrations of H₂SeO₃, Cu²⁺ and In³⁺.

In further embodiments thin films made accordance with the teachings of the present invention had reduced cracking resulting from growing the thin films Se-poor, while the formation of secondary CuₓSe_{y} phases was attenuated by pretreatment of the Mo electrode by a short deposition process prior to growing the Cu(In,Ga)Se₂ films.

The present invention also provides an electrodeposition bath useful for making photovoltaic devices comprising a buffered aqueous solution having from approximately 2.50 mM to approximately 4.00 mM CuCl₂.2H₂O, from approximately 2.20 mM to approximately 4.80 mM InCl₃, from approximately 3.50 mM to approximately 6.00 mM GaCl₃, from approximately 4.20 mM to approximately 8.0 mM H₂SeO₃, and from approximately 0.20M to approximately 0.30 M LiCl; and wherein said electrodeposition bath has a pH from approximately 1.5 to 3.0.

Also provided is an electrodeposition bath useful for making photovoltaic devices comprising a buffered aqueous solution having from approximately 2.56 mM to approximately 3.55 mM CuCl₂.2H₂O, from approximately 2.40 mM to approximately 4.55 mM InCl₃, from approximately 3.73 mM to approximately 5.70 mM GaCl₃, from approximately 4.47 mM to approximately 7.8 mM H₂SeO₃, and approximately 0.24 M LiCl; and wherein said electrodeposition bath has a pH from approximately 1.8 to 2.5.

In another embodiment of the present invention the electrodeposition bath useful for making photovoltaic devices comprises a buffered aqueous solution having approximately 3.55 mM CuCl₂.2H₂O, approximately 4.55 mM InCl₃, approximately 3.73 mM GaCl₃, approximately 7.8 mM H₂SeO₃, and approximately 0.24 M LiCl; and wherein said electrodeposition bath has a pH is approximately 2.5.

Still another electrodeposition bath useful for making photovoltaic devices of the present invention comprises a buffered aqueous solution having approximately 2.56 mM CuCl₂.2H₂O, approximately 2.40 mM InCl₃, approximately 5.70 mM GaCl₃, approximately 4.47 mM H₂SeO₃, and approximately 0.24 M LiCl; and wherein said electrodeposition bath has a pH is approximately 2.5.

Yet another electrodeposition bath made in accordance with the teachings of the present invention has a H₂SeO₃ concentration of approximately 5.46 mM.

The thin film photovoltaic devices of the present invention have improved film morphology and thus permit processing of devices in accordance the teachings herein resulting in improved overall performance.

In one embodiment of the present invention, a method is provided for creating an electrodeposited film upon a substrate comprising the steps of: providing a buffered aqueous solution containing Cu, In and Se; providing an electrodeposition set-up in the buffered aqueous solution; placing the substrate in the buffered aqueous solution and performing deposition upon the substrate via the electrode electrodeposition set-up; and performing selenization upon the substrate in H₂Se/Ar. In another embodiment, the step of performing selenization upon the substrate in H₂Se/Ar is performed at 450° C. for 20 minutes in 0.35% H₂Se/Ar. In another embodiment, the method further comprises the step of performing selenization upon the substrate in Se-vapor after selenization of the substrate in H₂Se/Ar. In another embodiment, the method further comprises the step of performing selenization upon the substrate at 500° C. for 30 minutes in Se-vapor.

In one embodiment of the present invention, a method for creating an electrodeposited film upon a substrate comprising the steps of: providing a buffered aqueous solution containing Cu, In and Se; providing an electrodeposition set-up in the buffered aqueous solution; placing the substrate in the buffered aqueous solution and performing deposition upon the substrate via the electrode electrodeposition set-up; and performing selenization upon the substrate in Se-vapor. In another embodiment, the step of performing selenization upon the substrate in Se-vapor is performed at 500° C. for 30 minutes in 0.35% H₂Se/Ar.

In one embodiment of the present invention, a method is provided for creating an electrodeposited film upon a substrate comprising the steps of: providing a buffered aqueous solution containing Cu, In and Se; providing an electrodeposition set-up in the buffered aqueous solution; placing the substrate in the buffered aqueous solution and performing deposition upon the substrate via the electrode electrodeposition set-up; and performing sulfurization upon the substrate in H₂S/Ar. In another embodiment, the step of performing sulfurization upon the substrate in H₂S/Ar is performed at 550° C. for 30 minutes in H₂S/Ar.

In another embodiment, the buffered aqueous solution containing Cu, In and Se comprises CuCl₂, InCl₃ and H₂SeO₃.

In another embodiment, the buffered aqueous solution containing Cu, In and Se further comprises Ga. In another embodiment, the buffered aqueous solution containing Cu, In, Ga and Se comprises CuCl₂, InCl₃, GaCl₃ and H₂SeO₃.

In yet another embodiment, the electrodeposition set-up is a three-electrode electrodeposition set-up comprising a Mo electrode, a Pt mesh counter-electrode and a saturated calomel electrode reference electrode.

In another embodiment, a photovoltaic device produced according to the claimed methods is provided wherein the photovoltaic device has a conversion efficiency of at least 19%.

### BRIEF DESCRIPTION OF THE DRAWINGS

FIG. 1. SEM images of powdery CuIn_{0.83}Gao_{0.33}Se_{2.25} film deposited from buffered bath A onto a non-treated Mo electrode at −0.6 V for 60 minutes, (a) front view and (b) cross-section.

FIG. 2. Cross-section SEM images of Cu(In,Ga)Se₂ films deposited from buffered bath B, containing (a) [Se⁴⁺]/[Cu²⁺]=2.2 and (b) [Se⁴⁺]/[Cu²⁺]=1.75, onto non-treated Mo electrodes at −0.6 V for 70 minutes.

FIG. 3. Composition of Cu(In,Ga)Se₂ films deposited from buffered bath B onto non-treated Mo electrodes at −0.6 V for 70 minutes with varying (a) [H₂SeO₃] and (b) [Cu²⁺]. Lines are included to aid the eye. Dashed line indicates [Se⁴⁺]/[Cu²⁺]=1.75.

FIG. 4. Composition of Cu(In,Ga)Se₂ films deposited from buffered bath B onto non-treated Mo electrodes at −0.6 V for 70 minutes with varying [In³⁺]. Lines are included to aid the eye. Dashed line indicates standard bath [In³⁺].

FIG. 5. Composition of Cu(In,Ga)Se₂ films deposited from buffered bath B onto non-treated Mo electrodes at −0.6 V for 70 minutes with varying [Ga³⁺]. Lines are included to aid the eye. Dashed line indicates standard bath [Ga³⁺].

FIG. 6. Composition of Cu(In,Ga)Se₂ films deposited at various potentials from buffered bath B onto non-treated Mo electrodes for 70 minutes. Lines are included to aid the eye.

FIG. 7. XRD patterns of Cu(In,Ga)Se₂ films from FIG. 6. Angle of incidence was 0.50°.

FIG. 8. SEM images of Cu(In,Ga)Se₂ films from FIG. 6.

FIG. 9. SEM images of Cu(In,Ga)Se₂ film deposited from buffered bath B at −0.5V for 20 minutes followed by −0.6V for 50 minutes onto a Mo electrode pretreated with a 1 minute deposition from the bath at −0.5 V, (a) front view and (b) cross-section.

FIG. 10. XRD patterns of an ED Cu(In,Ga)Se₂ film deposited from buffered bath B at −0.5V for 20 minutes followed by −0.6V for 50 minutes onto a Mo electrode pretreated with a 1 minute deposition at −0.5 V from the bath (a) as-deposited and (b) after selenization in H₂Se/Ar at 450° C. for 20 min and (c) after selenization in Se vapor at 500° C. for 20 minutes. Inset shows the 112 reflections on expanded scale.

FIG. 11. GIXRD patterns of Cu(In,Ga)Se₂ film deposited from buffered bath B at −0.5V for 20 minutes followed by −0.6V for 50 minutes onto a Mo electrode pretreated with a 1 minute deposition at −0.5 V from the bath at incidence angles of (a) 5°, (b) 2°, (c) 1°, (d) 0.5°. Inset shows the 112 reflections on expanded scale.

FIG. 12. J-V curves for the best device prepared using Cu(In,Ga)Se₂ film deposited from buffered bath B at −0.5V for 20 minutes followed by −0.6V for 50 minutes onto a Mo electrode pretreated with a 1 minute deposition at −0.5 V from the bath.

FIG. 13. SEM image of ED CuInSe₂ film prepared from a bath containing [Se⁴⁺]/[Cu²⁺]≧2.

FIG. 14. SEM image of an ED CuInSe₂ film after selenization in H₂Se/Ar at 500° C. for 30 mins.

FIG. 15. SEM image of an ED Cu(In,Ga)Se₂ film, deposited on a pre-treated Mo electrode, after selenization in H₂Se/Ar at 450° C. for 20 mins.

FIG. 16. Typical XRD patterns of ED CuInSe₂ films (a) as-deposited and (b) after selenization process in H₂Se/Ar at 500° C. for 30 mins.

FIGS. 17. Typical XRD patterns of ED Cu(In,Ga)Se₂ films (a) as-deposited and (b) after selenization at 450° C. for 20 mins.

FIG. 18. J-V curves for the best device prepared using ED CuInSe₂ films.

FIG. 19. J-V curves for the best device prepared using ED Cu(In,Ga)Se₂ films.

FIG. 20. CV plots, showing first two scans, and film composition versus deposition potential of Cu—Se (A), Cu—In—Se (B), Cu—Ga—Se (C) and Cu—In—Ga—Se (D) baths.

FIG. 21. CuKα broad scan of a CuInSe₂ film (a) after annealing in Ar/O₂ at 550° C. for 30 min, (b) after annealing in H₂S at 550° C. for 15 min, (c) for 30 min and (d) for 45 min, respectively. Inset shows the shift of the 112 peak towards higher angles with substitution of S for Se.

### DETAILED DESCRIPTION OF THE INVENTION

The present invention provides methods for the electrodeposition of Cu(In,Ga)Se₂ films from single buffered aqueous baths and photovoltaic devices derived therefrom. In one embodiment, deposition conditions including bath concentrations, deposition potential and the nature of the electrode surface, resulted in production of as-deposited films with smooth morphology and good control of composition.

The photovoltaic devices produced according to the methods of the present invention have conversion efficiencies of between approximately 8% and more than 20%. In one embodiment the conversion efficiency is approximately 8%. In another embodiment, the conversion efficiency is approximately 12%. In another embodiment, the conversion efficiency is approximately 15%. In another embodiment, the conversion efficiency is approximately 19%. In another embodiment, the conversion efficiency is more than 19%.

All chemicals, copper(II) chloride dihydrate (CuCl₂.2H₂O 99+%), indium(III) chloride (InCl₃ 98%), selenious acid (H₂SeO₃, 98%), gallium(III) chloride (GaCl₃, 99.99+%), LiCl (99%), sulfamic acid, potassium biphthalate, KOH, pHydrion pH=3 buffer (all Aldrich) and KCN (Fisher), are used as received. Electrodeposition of Cu(In,Ga)Se₂ is carried out using acidic aqueous baths containing CuCl₂.2H₂O, InCl₃, GaCl₃ and H₂SeO₃, with LiCl added as the supporting electrolyte. The baths are buffered using a pH=3 pHydrion buffer, a sulfamic acid/potassium biphthalate mixture, giving bath pH˜2.5. The supplied buffer preservation solutions are not used in the baths.

For Cu(In,Ga)Se₂ deposition, two concentration regimes are used; a higher concentration buffered bath (bath A), containing 3.55 mM CuCl₂.2H₂O, 4.55 mM InCl₃, 3.73 mM GaCl₃, 7.8 mM H₂SeO₃, and 0.24M LiCl, and a lower concentration buffered bath (bath B) containing 2.56 mM CuCl₂.2H₂O, 2.40 mM InCl₃, 5.70 mM GaCl₃, 4.47 or 5.46 mM H₂SeO₃, and 0.24M LiCl. To maintain an acidic solution during bath preparation and prevent precipitation of In and Ga hydroxides, baths should always be prepared by mixing the Cu²⁺, In³⁺, Ga³⁺ and H₂SeO₃ solutions to a LiCl solution, before adding to a solution of dissolved buffer and diluting to a volume of 500 cm³. With the addition of the buffer species, baths are stable over a time period of weeks, with no precipitation of metal oxides observed during storage. The baths are stable during deposition and around ten Cu(In,Ga)Se₂, ˜2 μm thick, films can be deposited from a 500 cm³ low concentration bath without significant depletion of bath species.

A three-electrode electrodeposition set-up can be used, employing a Pt mesh counter-electrode and a saturated calomel electrode (SCE) reference electrode. All potentials are reported with respect to SCE. The working electrodes are preferably 1″×1″ dc-sputtered 0.7 μm Mo layers, deposited on soda-lime glass. The Mo films should be washed prior to deposition by sonication in warm water and detergent (Liquinox) for 5 minutes and then well rinsed with DI water and sonicated for a further 5 minutes. Depositions are preferably carried out using a Princeton Applied Research 263A potentiostat or the like. All depositions can be carried out at room temperature from slowly stirred baths. Purging the baths with Ar(g) prior to deposition is found to have no effect on the deposition and was generally not used.

### EXAMPLE 1

Deposition of Cu(In,Ga)Se₂ was generally carried out at −0.6 V for 60-90 minutes. Films of improved morphology were obtained when a short electrode pretreatment, of a 1 minute deposition at −0.5V from the bath was carried out prior to deposition of the film. Following pretreatment, the substrate was removed from the bath, rinsed and dried in an Ar(g) stream before returning to the bath and completing deposition with a multi-potential sequence of −0.5V for 20 minutes, followed by −0.6 V for 50 minutes.

On completion, films were rinsed and dried in an Ar(g) stream. Selenization treatments of the Cu(In,Ga)Se₂ films were carried out at 450° C. in a 0.35% H₂Se/Ar(g) (Scott Specialty Gases) atmosphere for 20 minutes in a laminar flow thermal chemical vapor deposition reactor at atmospheric pressure as previously described by Engelmann et al. (Thin Solid Films, 387:14, 2001). For comparison, some films were selenized at 525° C. in Se vapor during 30 minutes in a physical vapor deposition (PVD) system, with Se source temperature at 250° C. For device processing, H₂Se-selenized films were etched in aqueous 0.5 M KCN solutions for 1 minute at 55° C. and were completed by sequential deposition of CdS by chemical bath deposition, and sputtered ZnO:Al and Ni/Al grids using a baseline process described by Shafarman et al. (J Appl Phys, 79:7324,1996).

X-ray diffraction (XRD) was carried out using a Philips/Norelco diffractometer with Bragg-Brentano focusing geometry and CuKα radiation at 35 kV. Glancing incidence X-ray diffraction (GIXRD) measurements were obtained using a Rigaku D/Max 2500 system with parallel beam optical configuration and CuKα radiation at 40 kV. Scanning electron microscopy (SEM) was carried out using an Amray 1810 T scanning electron microscope at 20 kV attached with an Oxford Instrument Energy 200 energy dispersive x-ray spectroscopy (EDS) analytical system using evaporated Cu(In,Ga)Se₂ films as standards. Current Voltage (J-V) curves were measured using an Oriel Xenon solar simulator at AM 1.5 and 25° C.

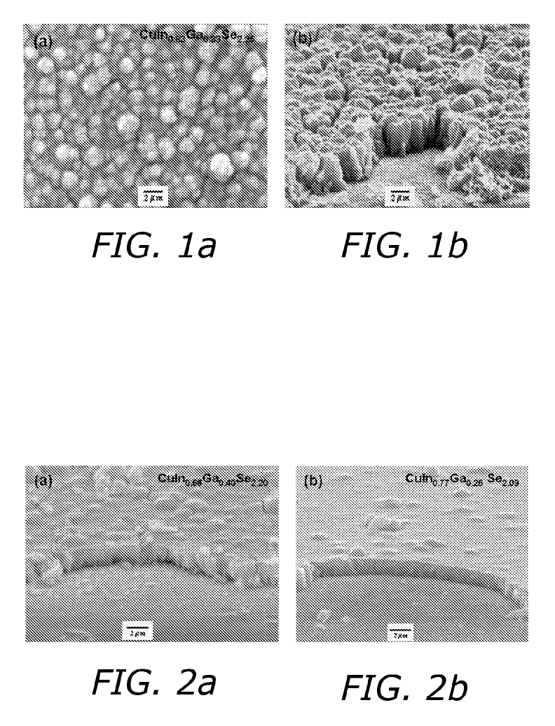

FIG. 1 depicts the SEM image of a Cu(In,Ga)Se₂ film deposited from bath A at −0.6V without pretreatment of the Mo electrode. Deposition of Cu(In,Ga)Se₂ from bath A, was found to consistently deposit dark and powdery films, containing large porous grains of ˜1-1.5 pm in size. Formation of bubbles was also observed on the electrode and growing film during deposition from this bath. Despite the appearance of the films, good film stoichiometry was obtained; 22.8% Cu, 18.5% In, 7.4% Ga, and 51.3% Se, giving a stoichiometry of CuIn_{0.83}Ga_{0.33}Se_{2.25} (normalized with Cu=1, unless otherwise stated) when considering just these species. The porous structure of the film is likely due to the high bath concentration, which produces excessive current density and allows the reduction of H₃O⁺ ions to H₂(g) in the acidic bath (reaction 1), which competes with Cu(In,Ga)Se₂ growth at this potential, to dominate the electrode reaction. This is confirmed by the formation of H₂(g) bubbles during deposition from bath A, which disrupt the film growth and structure and produce a porous deposit. Deposition at these conditions can also result in significant pitting and corrosion of the Mo electrode.
2H₃O⁺(aq)+2e⁻→H₂(g)+2H₂O(aq) (Reaction 1)

The bath pH window for the simultaneous deposition of Cu, In, Ga and Se at desired ratios was determined. Cu(In,Ga)Se₂ films deposited from non-buffered bath A, pH=1.8, contained very low, <1%, levels of Ga Increasing the pH of the non-buffered bath A to 2.1-2.4 with KOH lead to deposition of films containing a high proportion of Ga (˜12%) and O (˜40%), indicating significant levels of Ga(OH)₃. Baths of pH>2.7, with or without buffer, are unstable and, on mixing, In(OH)₃ and Ga(OH)₃ precipitate readily. Huang et al. have reported that variation in the pH of CuInSe₂ baths resulted in H₂ evolution and precipitation of indium hydroxide on the film surface during growth, which was avoided by addition of buffer to the baths. In the current study, following the approach of Bhattacharya and Fernandez (Sol Energy Mater Sol Cells, 76:331, 2003), pH=3 pHydrion buffer, a potassium biphthalate/sulfamic acid mixture, was added to stabilize the solution chemistry and film growth. Deposition of Cu(In,Ga)Se₂ from buffered bath A showed incorporation of 6-10% Ga and ˜15% O. The presence of buffer attenuates precipitation and deposition of metal hydroxides during film growth by stabilizing the pH at the electrode through scavenging of OH⁻ ions generated by the hydrogen evolution reaction (reaction 1). Addition of just potassium biphthalate to the bath, raised pH to ˜2.7 and resulted in precipitation of metal hydroxides in the solution, while addition of just sulfamic acid lowered pH to <2, which resulted in deposited films containing low Ga.

### EXAMPLE 2

Deposition from buffered baths of lower concentrations (bath B), resulted in growth of smooth and compact, silvery-gray films without formation of H₂(g) bubbles. FIG. 2 depicts SEM images of Cu(In,Ga)Se₂ films grown from buffered bath B at −0.6 V without electrode pretreatment. FIG. 2a shows a cross-section SEM image of Cu(In,Ga)Se₂ deposited from bath containing a [H₂SeO₃] to [Cu²⁺] ratio ([Se⁴⁺]/[Cu²⁺])=2.2, corresponding to bath [H₂SeO₃] and [Cu²⁺] of 5.46 and 2.56 mM, respectively. The films show columnar grain growth with a film thickness of ˜2 μm. Films grown from these conditions always exhibited cracking and contained significant secondary phases, resembling cauliflower-like florets ˜1-2 μm in size, embedded in the film surface. EDS results tentatively suggest these phases are Cu- and Se-rich.

FIG. 2b depicts a cross-section SEM image of Cu(In,Ga)Se₂ deposited from bath containing [Se⁴⁺]/[Cu²⁺]=1.75, with bath [H₂SeO₃] adjusted to 4.47 mM. This film has similar properties but no cracking is observed due to the lowering of the Se content of the film from 53% to 50%. Film compositions of ˜24-25% Cu, 17-19% In, 6-8% Ga and ˜50% Se, when just considering these species, can be consistently obtained at these conditions. Films deposited from buffered bath B also contain ˜15% O. At an applied potential of −0.6 V, electroplating of In and Ga metals is not expected, though significant assimilation of these metals into the deposited films is observed. This suggests an underpotential deposition mechanism for the incorporation of these species into the growing films, similar to that suggested for single-step electrodeposition of CuInSe₂ films.

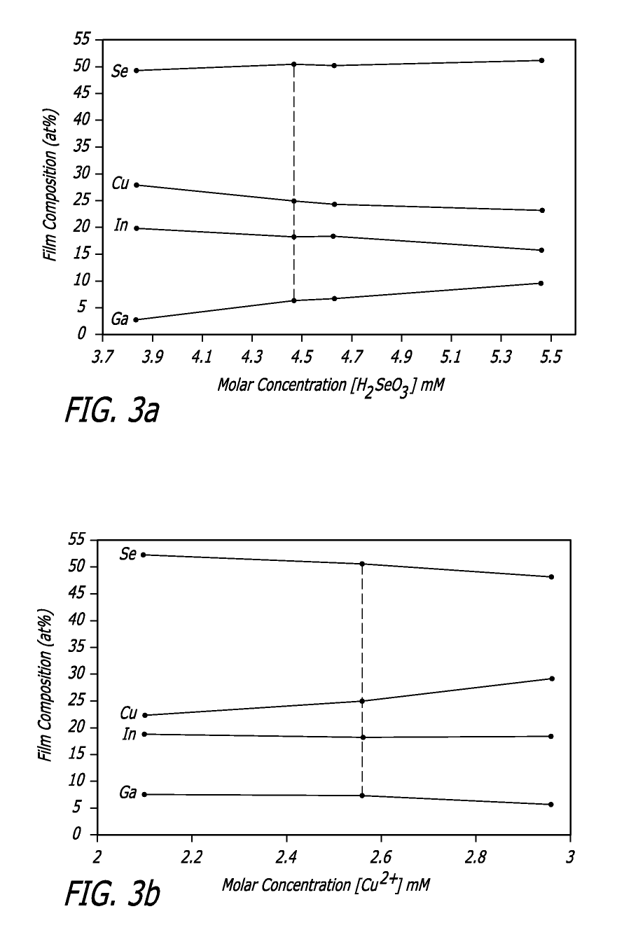

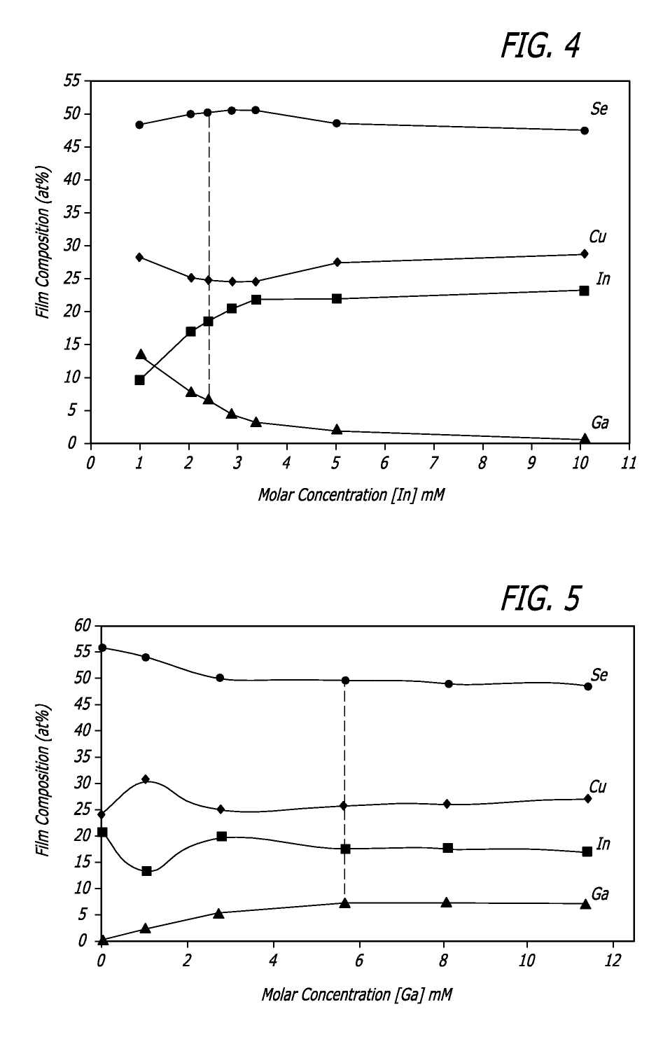

FIG. 3 depicts plots of composition of films deposited from buffered bath B, without electrode pretreatment, with varying [H₂SeO₃], between 3.8 and 5.5 mM (FIG. 3a), and [Cu²⁺], between ˜2-˜3 mM (FIG. 3b). Increasing [H₂SeO₃] results in a slight increase of deposited Se and a corresponding rise in deposited Ga, while the Cu and In components decrease. With increasing [Cu²⁺], the level of deposited Cu increases, at the expense of Se and Ga, while In levels remain constant. Cu(In,Ga)Se₂ films grown from baths with [Se⁴⁺]/[Cu²⁺]>1.75, are always Se-rich and consistently exhibit cracking (FIG. 2a). Films grown at [Se⁴⁺]/[Cu²⁺]<1.75 are Cu-rich and often poorly adhere to the Mo substrate. The best quality films were obtained from baths of [Se⁴⁺]/[Cu²⁺]=1.75 (FIG. 2b), which is highlighted on the plots. FIG. 4 depicts a plot of film composition deposited without electrode pretreatment from buffered bath B with varying [In³⁺]. With increasing [In³⁺], the level of deposited In increases steadily, with a corresponding decrease in deposited Ga, before stabilizing at ˜22% In at [In³⁺]˜3 mM, while the Cu and Se compositions remain relatively constant over all concentrations. Over all [In³⁺], the sum of deposited In and Ga levels is consistently ˜24-25%.

FIG. 5 depicts composition of films deposited from buffered bath B without electrode pretreatment with varying [Ga³⁺]. With increasing [Ga³⁺], the level of deposited Ga increases steadily, but stabilizes at ˜7%, with [Ga³⁺]˜6 mM. A steady decrease in Se content and a significant variation in Cu and In levels are observed before all three species stabilize at [Ga³⁺]˜3 mM. These observations indicate that bath [In³⁺] can be used to directly tune In and Ga levels in electrodeposited Cu(In,Ga)Se₂. Adjusting the concentration of LiCl electrolyte in bath B, between 0.15-0.5 M, had no effect on the composition of deposited films. However, the rate of film growth increased at higher concentrations, which resulted in significant cracking of films deposited from baths of [LiCl]>0.24 M.

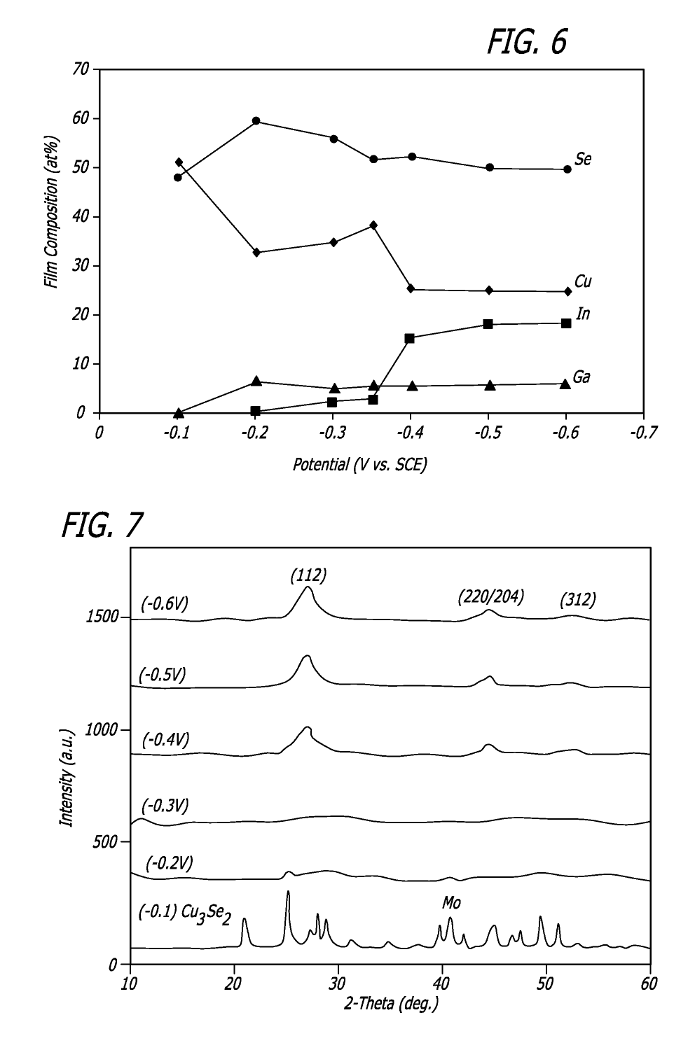

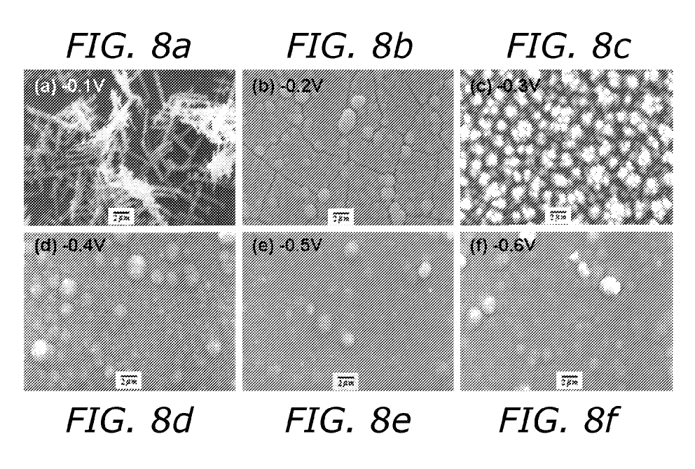

FIG. 6 graphically depicts the composition of Cu(In,Ga)Se₂ films deposited at different potentials between −0.1 V to −0.6 V from buffered bath B without electrode pretreatment. FIG. 7 and FIG. 8 depict XRD plots and SEM images, respectively, of these films. From FIG. 6, the film deposited at −0.1V contains ˜50% Cu and ˜50% Se, suggesting deposition of CuSe, however, XRD (FIG. 7) indicates only the presence of a thin crystalline Cu₃Se₂ film (JCPDS 47-1745). The discrepancy in film composition may be due to the presence of amorphous elemental Se or other copper selenides (CuₓSe_{y}). To more negative potentials, the Se profile initially increases for the film deposited at −0.2V, before decreasing to stabilize at 50% at potentials below −0.35V. Cu levels show a significant decrease at −0.2V and a further decrease for the film grown at −0.4V, dropping to ˜25%. The latter decrease corresponds with a significant increase in In uptake to ˜18%. Approximately 6% Ga is consistently detected in films deposited at −0.2V and below. Composition remains near constant for films deposited between −0.4V and −0.6V. H₂ bubbling and severe corrosion of the Mo electrode was observed during depositions below −0.6V. The XRD data (FIG. 7) shows a conversion from Cu₃Se₂ to a CuInSe₂/Cu(In,Ga)Se₂ structure for films deposited at −0.1V and −0.4V, with reflections appearing at ˜27.0° (112), ˜44.5° (220/204) and ˜52.6° (312). The broad diffuse appearance of the Cu(In,Ga)Se₂ reflections indicates the deposited films are of low crystallinity and small grain size. The structure of films deposited at potentials more negative than −0.4V remains constant. The morphology of the films, from the SEM images in FIG. 8, shows a similar trend, with a dramatic change in morphology between films deposited from −0.1V, consisting of needle-like Cu₃Se₂ crystals, to those deposited at −0.4V and below, where the films appear smooth and compact, though the cauliflower-like secondary phases are still present.

### Multiple-Potential Regime and Electrode Pretreatment

Devices processed with films with a high frequency of secondary phases typically exhibit shunting effects. Deposited film composition is found to have some effect on the frequency of these phases, with fewer growths observed for films with low Ga (<4%). The cauliflower-like phases appear to penetrate through the top ˜1-2 μm of the film. They survive post-deposition selenization treatments, but partially dissolve with aqueous KCN etching, leaving pits in the film surfaces, confirming the growths are likely CuₓSe_{y} phases. Oliveira et al. reported similar secondary phases in electrodeposited CuInSe₂ films, which were CuSe- or In₂Se₃-rich, depending on deposition time.

Using electrodes of different properties has a significant effect on deposited film morphology. For example, deposition of Cu(In,Ga)Se₂ on higher resistance −0.2 82 m thick Mo electrodes reduces the frequency of secondary phases with no effect on film composition. Deposition of Cu(In,Ga)Se₂ on Mo electrodes with surfaces oxidized by overnight storage in H₂O, which produces a surface mixture of MoO₂, MoO₃ and Mo hydroxides, also results in significant improvement of surface morphology with almost complete attenuation of the secondary phases. Similarly, Cu(In,Ga)Se₂ deposited directly on indium tin oxide/glass substrates is also almost completely free of cauliflower growths. These observations suggest that simple modifications of the electrode surface prior to deposition can be exploited to allow growth of smooth Cu(In,Ga)Se₂ films. A mixture of Mo electrode pretreatment, coupled with a multi-potential deposition regime, produces the best quality electrodeposited Cu(In,Ga)Se₂ films. This is accomplished by carrying out a short deposition treatment on the Mo electrode, by way of example, at −0.5V for 1 minute, using the same Cu(In,Ga)Se₂ bath. After the elapsed time, the substrate is removed from the bath, rinsed and dried, before continuing deposition at −0.5V for 20 minutes followed by −0.6V for 50 minutes.

### EXAMPLE 3

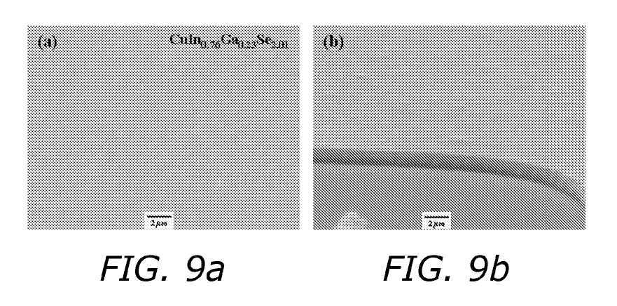

FIG. 9 depicts an SEM images of a Cu(In,Ga)Se₂ film grown from bath B on a treated Mo electrode. The film is almost completely free of secondary-growths, with no effect on composition (CuIn_{0.74}Ga_{0.27}Se_{2.03}, compare FIG. 2b). Devices processed with Cu(In,Ga)Se₂ films grown on pre-treated electrodes show improved performance, including no shunting effects. Analysis of the initial 1 minute deposited film showed it to be thin, ˜150 nm, smooth, and rich in Cu and Se with only a small amount of In. No Ga was detected, indicating the film is CuₓSe_{y}-rich. The GIXRD pattern of the 1 minute deposited film is very similar to the as-deposited CuInSe₂ film pattern, suggesting the 1 minute deposited film is likely dominated by Cu₂₋ₓSe, which has a diffraction pattern very similar to CuInSe₂.

The growth of the secondary phases may be due to the presence of pinholes in the growing film. These highly conductive sites will short to the Mo electrode resulting in formation of CuₓSe_{y}, which has been determined as a pre-cursor phase of electrodeposited CuInSe₂ films (see later discussion). Due to the high conductivity of the pinholes, CuₓSe_{y} will continue to grow at a faster rate than the inclusion of In³⁺ and Ga³⁺, resulting in the formation of the floret-like structures, similar to those observed to form at pinholes during electrodeposition of Cu on thin Al₂O₃ films deposited on conducting electrodes. This is also consistent with the observed shunting of devices processed with Cu(In,Ga)Se₂ containing a high frequency of cauliflower-like secondary phases. The improvements in film morphology is likely due to a reduction of pinhole frequency due to slower film growth on higher resistance electrodes or, in the case of the short deposition electrode pretreatment, the filling-in of pinholes formed during initial film nucleation by restarting deposition during the early stages of film growth.

### EXAMPLE 4

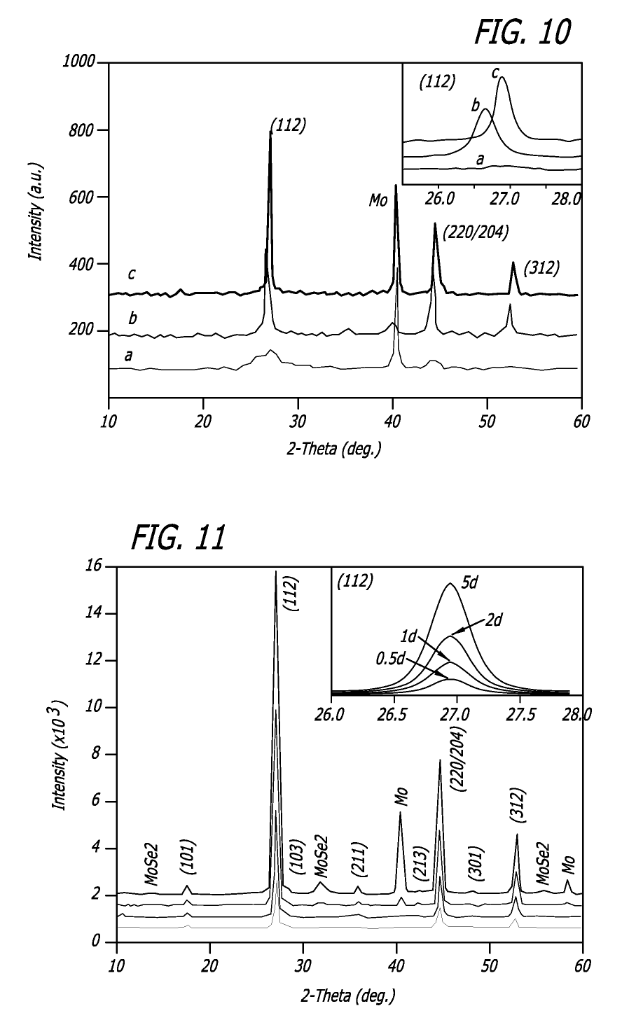

FIG. 10 depicts XRD patterns of Cu(In,Ga)Se₂ films, deposited from bath B onto pretreated Mo electrodes, as-deposited, following selenization at 450° C. for 20 minutes in 0.35% H₂Se/Ar and following selenization in Se vapor at 500° C. for 20 minutes. After H₂Se-selenization, films become light silvery gray in color and remain smooth and compact with columnar growth. The XRD pattern of the H₂Se-selenized film shows sharp and well defined peaks, indicating recrystallization of the film, and indicates approximately random orientation. The recrystallization begins within the first few minutes of annealing and is generally completed by 20 minutes. The expected shift of the (112) reflection, from d=3.348 to 3.314 (FIG. 10, line c inset), with the addition of Ga to the CuInSe₂ structure is observed for the H₂Se-selenized film and is consistent with a film stoichiometry of CuIn_{0.76}Ga_{0.23}Se_{2.0} (see, for example, JCPDS 35-1102). No evidence of Ga segregation is indicated from the XRD pattern, indicating uniform composition throughout the film thickness. This was confirmed from GIXRD measurements.

FIG. 11 depicts GIXRD patterns of the H₂Se-selenized Cu(In,Ga)Se₂ film, deposited from buffered bath B onto pretreated Mo, obtained with varying incident angles to sample to different depths. All patterns are near identical, indicating uniform composition and crystal structure throughout the film thickness. Following selenization in H₂Se, complete displacement of O from the film and only a minor, <1%, loss of Se is observed, making the film slightly Cu-rich. In contrast, preliminary selenization treatments of electrodeposited Cu(In,Ga)Se₂ films in Se vapor resulted in incomplete recrystallization and severe cracking of the films. Film compositions showed significant loss of Se, from ˜50% to ˜43%, but with little change for the metals or O content. XRD analysis of the Se-selenized film (FIG. 10, line b inset) confirmed the formation of CuInSe₂ (112, d=3.341), indicating Ga was not incorporated into the chalcopyrite structure and is likely present in an amorphous phase, possibly Ga oxide/hydroxide.

### Optimization of Photovoltaic Device Production

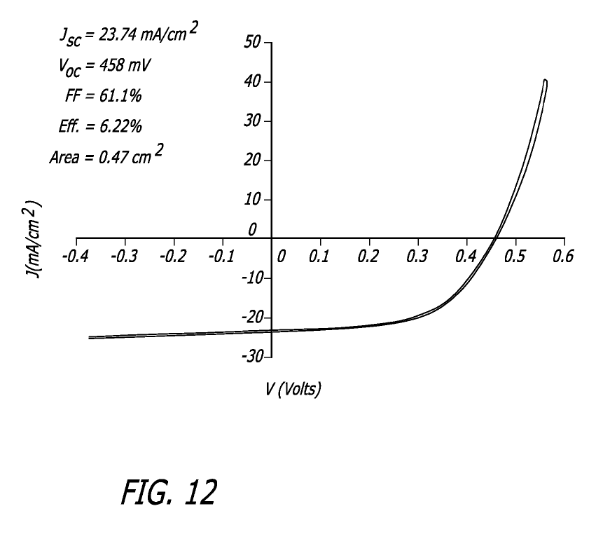

Photovoltaic devices made in accordance with the teachings of the present invention are typically processed from H₂Se-selenized Cu(In,Ga)Se₂ films, receiving a KCN etch, followed by CBD of CdS, and completed with sputtered ZnO:Al and Ni/Al grids. As previously mentioned, the presence of the CuₓSe_{y} secondary phases leads to shunting of devices processed with Cu(In,Ga)Se₂ films prepared on Mo electrodes without pretreatment. Devices processed with Cu(In,Ga)Se₂ films grown on pre-treated Mo electrodes show improved PV performance, including absence of shunting effects. FIG. 12 depicts the J-V plot of Cu(In,Ga)Se₂ device, deposited on a modified Mo electrode from bath B. The J-V parameters of this device are; area=0.47 cm², V_{OC}=458 mV, J_{SC}=23.74 mA/cm², fill factor=61.1% and η=6.2%. The low current collection, observed for the Cu(In,Ga)Se₂ thin film device can be due to incomplete processing of the absorber layer. Improvements in device performance are expected with optimization of post-deposition processing.

The composition and morphology of Cu(In,Ga)Se₂ films are sensitive toward changes in bath and deposition conditions. In particular, [Se⁴⁺]/[Cu²⁺], [In³⁺] and bath pH must be controlled to ensure successful depositions of Cu(In,Ga)Se₂ films. The use of buffer allows growth of films of compositions adequate for device processing. The buffer alleviates pH changes during deposition and stabilizes the Cu²⁺ ions by complexation and beneficially slow film growth by blocking diffusion of the metal ions to the electrode.

The deposition of CuInSe₂ generally involves an initial deposition of CuₓSe_{y} phases, though the mechanism of CuₓSe_{y} formation is not confirmed. The observations disclosed herein of the Cu₂₋ₓSe-rich 1 minute deposited pretreatment films, and the deposition of Cu₃Se₂ at −0.1 V, confirms the initial stages of film growth are dominated by the formation of copper selenide phases. Both Cu₂₋ₓSe and Cu₃Se₂ phases have been reported as initial products of CuInSe₂ electrodeposition. Incorporation of In into Cu(In,Ga)Se₂ films was observed in this work at ˜0.4V and below (FIG. 6), similar to that observed for electrodeposited CuInSe₂. However, the chemistry of the uptake of In is not well understood. The proposed pathway of In³⁺ inclusion is via reduction of the CuₓSe_{y} phase, which has been confirmed from CV to occur potentials more negative than −0.4 V, 40 to form Cu⁰ and dissolved H₂Se or Se²⁻, though H₂Se(aq) would be the expected majority species of aqueous Se²⁻ at pH<3. The formation of In₂Se₃, ΔG_{f}^{o}=−386 kJ/mol, at the electrode surface is expected on generation of H₂Se(aq). The free energy of formation of CuInSe₂, however, has been shown to be 10-80 kJ more stable than the mixture of the Cu₂Se+In₂Se₃ binaries, indicating that In₂Se₃ will be rapidly assimilated into the growing CuInSe₂ film. The generated Cu⁰ will likely react with H₂Se(aq) or deposited Se to generate further CuₓSe_{y}.

Kemmel et al. (J Electrochem Soc, 147:1080, 2000), employing Cu(SCN)₄⁻ (aq) as the source of Cu, suggest that the H₂Se mechanism is unlikely, as deposition of stoichiometric CuInSe₂ was observed to occur at potentials more positive than generation of H₂Se. Further mechanisms were proposed, involving Se⁰(s) and HSeO₃⁻ (aq) as the sources of Se²⁻, though the general mechanism remains similar. Oliveira et al. observed, by CV, an underpotential deposition of In, at −0.5V, on a CuInSe₂ film in an InCl₃ solution which does not occur at similar conditions on Mo electrodes.

Due to the similarity of the systems, and the similarity of In³⁺ and Ga³⁺ aqueous chemistry, it may be expected that the growth chemistry of electrodeposited Cu(In,Ga)Se₂ will be similar to that of CuInSe₂. Uptake of Ga in the growing films occurs at potentials as high as −0.2V (FIG. 6), though the amount of incorporated Ga remains constant over all deposition potentials. Plating of Ga metal will occur at the bath conditions disclosed herein onto Mo or growing chalcopyrite films, and a similar mechanism to In incorporation may be involved, via formation and assimilation of Ga₂Se₃ into the growing film by reaction with CuₓSe_{y} or CuInSe₂. However, no Ga was detected in the 1 minute deposited electrode pretreatment films, though some In was present, suggesting that incorporation of Ga is slow compared to the inclusion of In. However, the absence of Ga in Cu(In,Ga)Se₂ films grown from baths at pH<2 suggests that the incorporation of Ga cannot involve a redox step. This is consistent with preliminary CV measurements, where similar behavior is observed for CuInSe₂ and Cu(In,Ga)Se₂ baths of similar concentrations at Mo film electrodes. The high O content of the as-deposited films suggests that Ga, and possibly significant levels of In, is incorporated into the deposited films via limited precipitation of the metal hydroxide by reaction with OH⁻(aq) ions at the electrode surface. In the absence of buffer, films deposited at pH˜2.6 contained high levels of GaOH₃. Due to the solubility of Ga(OH)₃ in acidic conditions, films grown from baths at pH<2 are, therefore, expected to contain only low levels of Ga, as is observed. Following selenization in H₂Se, however, almost all O is removed from the film and XRD confirms the formation of Cu(In,Ga)Se₂.

In comparison, Cu(In,Ga)Se₂ films selenized in Se vapor resulted in recrystallization of CuInSe₂, though significant Ga and O remained in the film. These observations indicate that selenization with H₂Se converts metal oxide/hydroxides and allows assimilation of Ga into the CuInSe₂ structure, and may be required to successfully process electrodeposited Cu(In,Ga)Se₂ devices. H₂Se has been previously reported to be superior to Se vapor for selenization of metals films for Cu(In,Ga)Se₂ processing and, in particular, exhibits more efficient conversion of metal oxides.

### EXAMPLE 5

In another group of experiments in accordance with the general teachings of the present invention, the ED of CuInSe₂ was carried out using acidic aqueous baths containing 2.6 mM CuCl₂.2H₂O, 9.6 mM InCl₃ and 5.5 mM H₂SeO₃, with 0.236M LiCl added as the supporting electrolyte. For Cu(In,Ga)Se₂ deposition baths containing ˜2.5 mM CuCl₂.2H₂O, 2.4 mM InCl₃, ˜5.8 mM GaCl₃, ˜4.5 mM H₂SeO₃, and 0.236M LiCl were used. All baths were buffered using a pH=3 pHydrion buffer, giving pH˜2.6 for both bath types. A three-electrode ED set-up was used, employing a Pt mesh counter-electrode and a saturated calomel electrode (SCE) reference electrode. The working electrodes were dc-sputtered Mo layers of 0.7 μm thickness. All depositions were carried out using a Princeton Applied Research 263A potentiostat at room temperature from a stirred bath. Depositions were initially carried out at −0.6 V (SCE) for 70 mins, however, the best CuInSe₂ films were obtained when a multi-potential regime, of 20 mins at −0.5 V (SCE) followed by 50 mins at −0.6 V (SCE), was used. The best quality Cu(In,Ga)Se₂ films were obtained when a short electrode pre-treatment, of a 1 min deposition at −0.5 V (SCE) from the Cu(In,Ga)Se₂ bath, was carried out. The substrate was then removed, rinsed and dried, before completing deposition at −0.5 V (SCE) for 20 mins, followed by −0.6 V (SCE) for 50 mins. Following deposition, films were rinsed with distilled water and dried under flowing argon.

Films were annealed in H₂Se/Ar at high temperature in a laminar flow thermal chemical vapor deposition reactor at atmospheric pressure previously described by Engelmann et al. The temperature, time and H₂Se concentration were used to control the reaction of the as-deposited films, though standard conditions were 450° C. to 550° C. for 20-30 mins in a 0.35% H₂Se/Ar atmosphere. Selenized films were generally etched in aqueous 0.5 M KCN solutions for 1 min at 55° C. to remove excess Cu.

X-ray diffraction (XRD) patterns of the films were obtained using a Phllips/Norelco diffractometer with CuKa radiation. The composition of the CuInSe₂/Cu(In,Ga)Se₂ films were measured by energy dispersive x-ray spectroscopy (EDS) in an Amray 1810 T scanning electron microscope (SEM) equipped with an Oxford Instrument Energy 200 EDS analytical system.

Devices were completed by sequential deposition of CdS, ZnO:Al and NI/Al grids using a baseline process described by Shafarman et al. Current Voltage (J-V) curves were measured using an Oriel Xenon solar simulator at AM1.5 and 25° C.

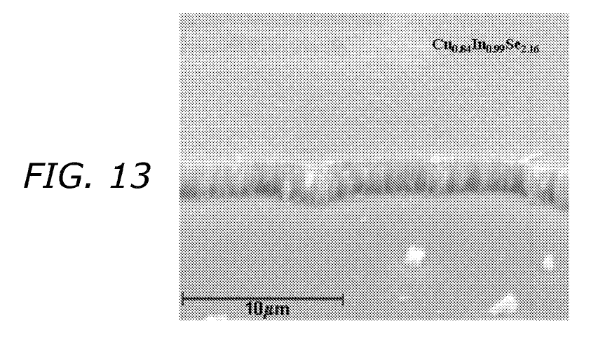

Single-bath ED of CuInSe₂ and Cu(In,Ga)Se₂, for PV device application, has been carried out from buffered low concentration baths. The resultant CuInSe₂ and Cu(In,Ga)Se₂ films are silvery-gray, smooth and compact. Control of the deposited film composition requires careful balance of the bath concentrations. The ratio of bath concentrations of H₂SeO₃ and Cu²⁺ ([Se⁴⁺]/[Cu²⁺]) was found to have a significant effect on composition and morphology of deposited films. For ED of CuInSe₂, [Se⁴⁺]/[Cu²⁺]>2 was found to allow growth of Cu-poor films of ˜23% Cu, ˜25% In and ˜52% Se, from a single bath. FIG. 13 shows an SEM image of an as-deposited CuInSe₂ film, of ˜2 μm thickness, with a smooth surface and well-defined columnar grains 0.5-0.75 μm in size.

For Cu(In,Ga)Se₂, films grown at [Se⁴⁺]/[Cu²⁺]>1.75 are always Se-rich and exhibit cracking and secondary phases, most likely Cu₂₋ₓSe, which appear as cauliflower-like florets (see FIG. 2a). Films grown at [Se⁴⁺]/[Cu²⁺]<1.7 are Cu-rich and poorly adhere to the Mo substrate. Baths of [Se⁴⁺]/[Cu²⁺]=1.75 (FIG. 2b) were found to consistently produce crack-free films of near stoichiometric Cu and Se compositions. Bath [In³⁺] was varied to adjust Ga composition, which allowed growth of Cu(In,Ga)Se₂ films ˜25% Cu, 17-20% In, 6-8% Ga and ˜50% Se, from a single deposition. The as-deposited Cu(In,Ga)Se2 films are 1.5-2 μm thickness and show well-defined columnar growth.

The presence of the Cu₂₋ₓSe secondary phases leads to shunting of devices processed with these Cu(In,Ga)Se₂ films. Modifying the Mo electrode properties prior to deposition, by pre-treatment with a 1 min deposition at −0.5 V (SCE), attenuated the formation of the secondary phases (FIG. 9b). This very thin initial film is predominantly Cu₂₋ₓSe, which has been determined as a pre-cursor phase of ED CuInSe₂/Cu(In,Ga)Se₂ films. Any pinholes present in this film will be filled in during the Initial stages of restarting deposition and thus prevent formation of the secondary phases. During growth of Cu(In,Ga)Se₂, the highly conducting pinholes may nucleate and grow Cu₂₋ₓSe at a faster rate than the slower In³⁺ and Ga inclusion reactions. This fast growth of Cu₂₋ₓSe at pinholes results in the formation of the floret-like structures.

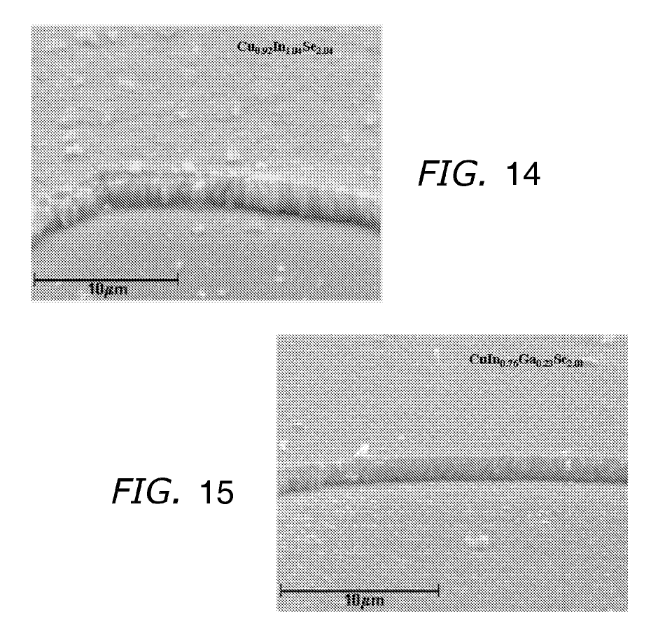

Following selenization, the ED CuInSe₂ film composition does not change considerably, though loss of Se, ˜2%, is sometimes observed, giving a final film composition of ˜5% Cu, ˜26% In and ˜49% Se. FIG. 14 shows the cross-section SEM image of an ED CuInSe₂ film after selenization at 500° C. for 30 min. For ED Cu(In,Ga)Se₂, the loss of Se is less than 1%, giving a final film composition of ˜25% Cu, ˜18% In, ˜7% Ga and ˜50% Se.

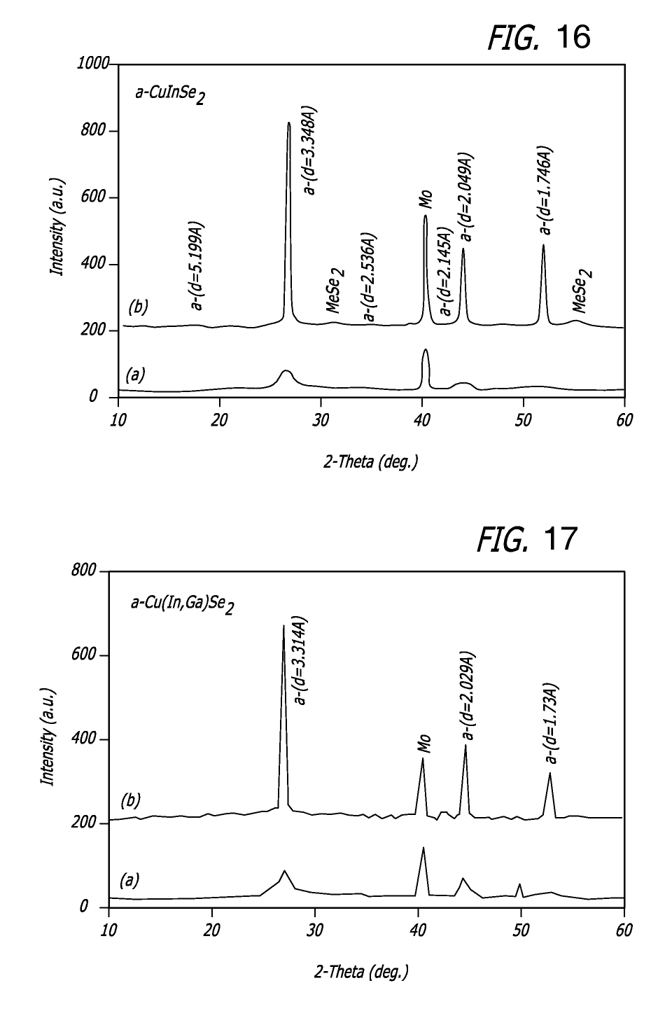

FIGS. 16 and 17 show XRD patterns of ED CuInSe₂ and Cu(In,Ga)Se₂ films, respectively, both as-deposited and following selenization treatment. The as-deposited films exhibit three main peaks; (112), (220, 204), and (312), corresponding to the CuInSe₂/Cu(In,Ga)Se₂ structure. The peaks are very broad and weak, indicating the films are of low crystallinity and small grain size. The peak located at 40.5°(110) corresponds to the main Mo peak (JCPDS 42-1120). No secondary phases are observed from the XRD data, except for MoSe₂, which is formed at the Mo/film interface during selenization at >450° C. (see FIG. 16, line b). After selenization, the CuInSe₂ 1films became dark gray in color. XRD indicated significant recrystallization, with peaks becoming sharp and well defined with approximately random orientation. The measured d-values are consistent with CuInSe₂ (JCPDS 40-1487, see FIG. 16, line b).

Cu(In,Ga)Se₂ films became light silvery-gray in color after selenization. XRD showed the expected shift of the (112) reflection with the addition of Ga (JCPDS 35-1102, see FIG. 17, line b). This recrystallization begins within the first few minutes of annealing and is generally completed by 20 mins. No evidence of Ga segregation is observed from the XRD data, indicating uniform composition throughout the film thickness. Because of Se loss during selenization, the films become slightly Cu rich and require an aqueous KCN etch to remove the excess Cu prior to completing devices.

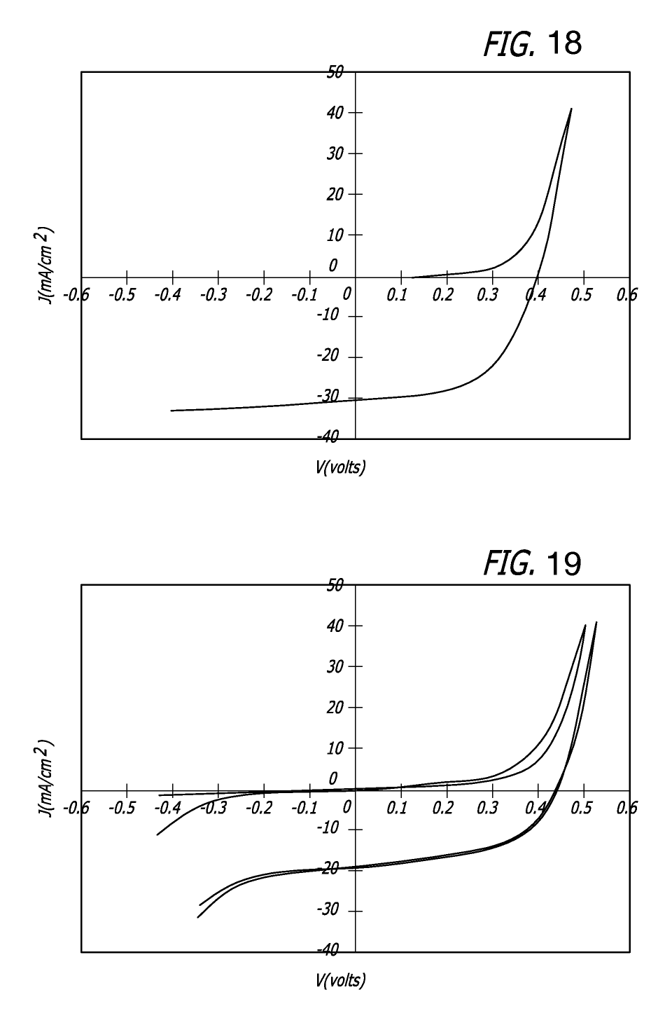

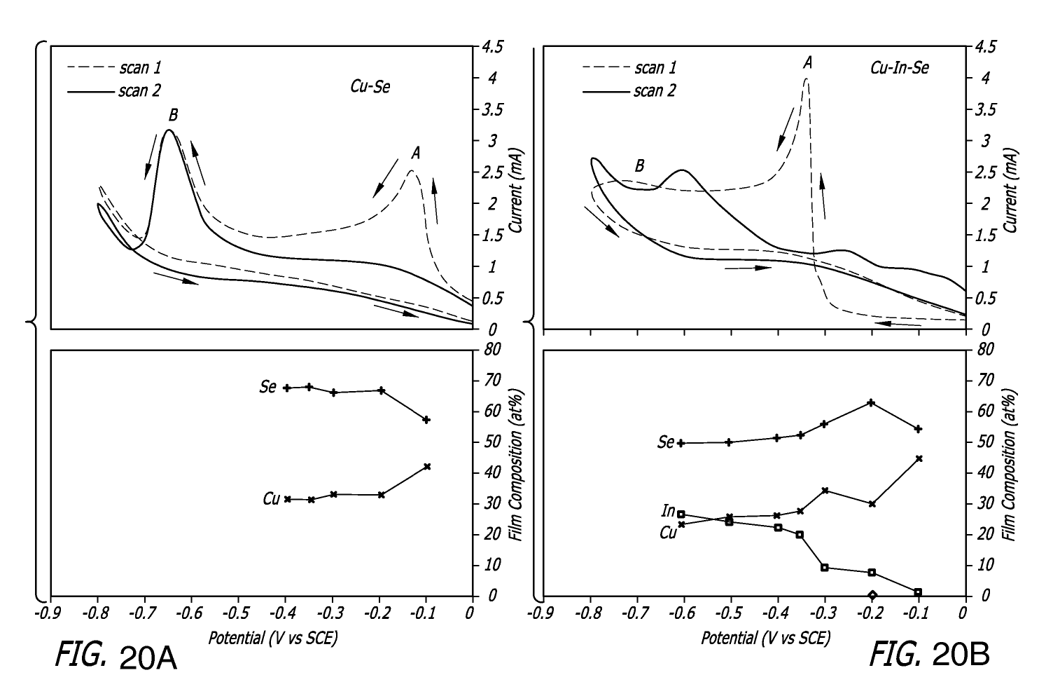

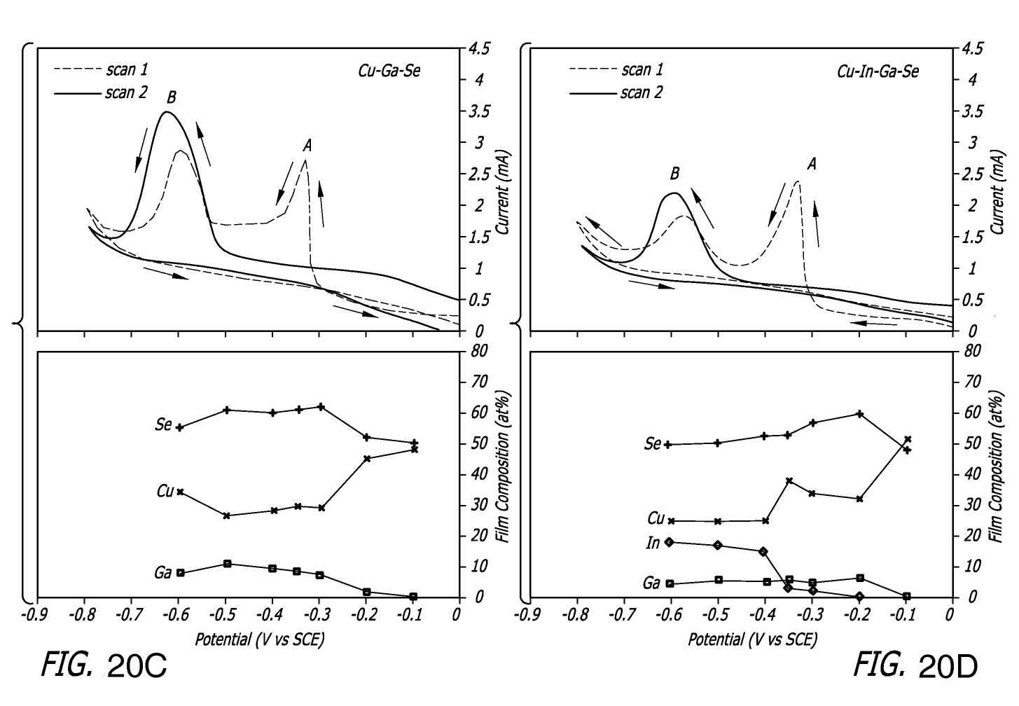

FIGS. 18 and 19 show the corresponding J-V curves for the best ED CuInSe₂ and Cu(In,Ga)Se₂ devices, respectively, measured in the dark and under illumination. The CuInSe₂ device exhibits diode behavior; area=0.47 cm², V_{OC}=400 mV, J_{SC}=29.89 mA/cm², FF=55.3% and η=6.65%.

The J-V parameters for the Cu(In,Ga)Se₂ device, deposited on a modified Mo, are; area=0.47 cm², V_{OC}=447 mV, J_{SC}=19.40 mA/cm², FF=52.4% and η=4.55%. The devices have not shown improvement with addition of Ga. The low current collection, observed for both types of devices, may be due to incomplete reaction and processing of the absorber layer. The apparent double diode effect observed for the Cu(In,Ga)Se₂ device may be due to conductive secondary phases present in the grain boundaries of the film. The device results are very promising, even though the J-V parameters are low compared to PVD processed devices. Improvements in device performance are expected with optimization of the post-deposition processing.

### EXAMPLE 6

Further, ED of CuInSe₂ was carried out using acidic aqueous baths containing 2.6 mM CuCl₂.2H₂O, 9.6 mM InCl₃ and 5.5 mM H₂SeO₃, with 0.236M LiCl added as the supporting electrolyte to improve bath conductivity. For Cu(In,Ga)Se₂ ED, baths containing 2.5 mM CuCl₂.2H₂O, 2.4 mM InC1₃, 5.8 mM GaCl₃, 4.5 mM H₂SeO₃, and 0.236M LiCl were used. All baths were buffered using a pH=3 pHydrion buffer, giving pH˜2.6 for both bath types. A three-electrode cell was used, employing a Pt mesh counter-electrode and a saturated calomel reference electrode (SCE). All potentials are reported with respect to SCE. The working electrodes were dc-sputtered Mo layers of 0.7 μm thickness. All depositions at constant potential were carried out using a Princeton Applied Research 263A potentiostat at room temperature from a stirred bath. The best quality Cu(In,Ga)Se₂ films were obtained when a short electrode pre-treatment, of a 1 min deposition at −0.5 V from the Cu(In,Ga)Se₂ bath, was carried out prior to deposition. The substrate was then removed, rinsed and dried, before completing deposition at −0.5 V for 20 mins, followed by −0.6 V for 50 mins. Following deposition, films were rinsed with distilled water and dried under flowing argon. For device processing, ED films were selenized in 0.35% H₂Se/Ar(g) at 400-550° C. Devices were completed by etching selenized films in aqueous 0.5 M KCN solutions for 1 min at 55° C., followed by application of chemical bath deposited CdS and sputtered ZnO:Al and Ni/Al grids.

CV experiments were carried out using a Princeton Applied Research 263A scanning potentiostat with the three-electrode ED set-up as above. The area of the Mo/glass electrodes was ˜1.6 cm. CV measurements were carried out in Cu—Se, Cu—In—Se, Cu—Ga—Se, and Cu—In—Ga—Se baths of similar concentrations to the CuInSe₂ and Cu(In,Ga)Se₂ ED baths. All solutions were purged with Ar(g). The CV scans were recorded between 0 to −0.8 V at a scan rate of 10 mV/sec. All subsequent scans were recorded immediately following the initial measurements. Films were deposited from these solutions at constant potentials between −0.1 to −0.6 V for 60 min on untreated Mo.

X-ray diffraction (XRD) was carried out using a Philips/Norelco diffractometer with Bragg-Brentano focusing geometry and CuKα radiation at 35 kV. GIXRD measurements were obtained using a Rigaku D/Max 2500 system with parallel beam optical configuration. Scanning electron microscopy (SEM) was carried out using an Amray 1810 T scanning electron microscope attached with an Oxford Instrument Energy 200 energy dispersive x-ray spectroscopy (EDS) analytical system. Current Voltage (J-V) curves were measured using an Oriel Xenon solar simulator at AM1.5 and 25° C.

### Further Optimization of Electrodeposited Films

A mixture of Mo electrode pretreatment coupled with a multi-potential deposition regime produces the best quality ED Cu(In,Ga)Se₂ films. Films thus can be made almost completely free of copper selenide secondary phases, (copper selenide secondary phases often appear as floret-like structures). The growth of these secondary phases is attenuated due to pretreatment of the Mo electrode.

These films are typically ˜2 μm thick with smooth and compact morphology. The deposited films are of composition suitable for PV application without requiring additional vacuum deposition steps to adjust final composition. The as-deposited films show broad weak peaks, indicating films are of low crystallinity and small grain size. After selenization in H₂Se the incorporation of Ga into the CuInSe₂ structure produces the expected shift of the (112) reflection (JCPDS 35-1102). However, for the Cu(In,Ga)Se₂ annealed in Se vapor peak position is not consistent with measured film composition, containing ˜7% Ga, indicating that the Ga is not being incorporated into the crystal structure (see FIG. 10). Successful processing of electrodeposited CuInSe₂-based devices has been made by annealing the as-deposited samples in H₂Se, reporting conversion efficiencies of 6.5% for CuInSe₂ and 6.2% for Cu(In,Ga)Se₂.

### Additional Examples

The mechanism of formation/reaction leading to the growth of CuInSe₂-based thin films from single-bath ED is not well understood. An understanding of the chemistry of film growth may allow further optimization and control of the deposition process and improve device performance. CV was thus used to provide insight about the mechanism of the early stages of CuInSe₂ and Cu(In,Ga)Se₂ growth.

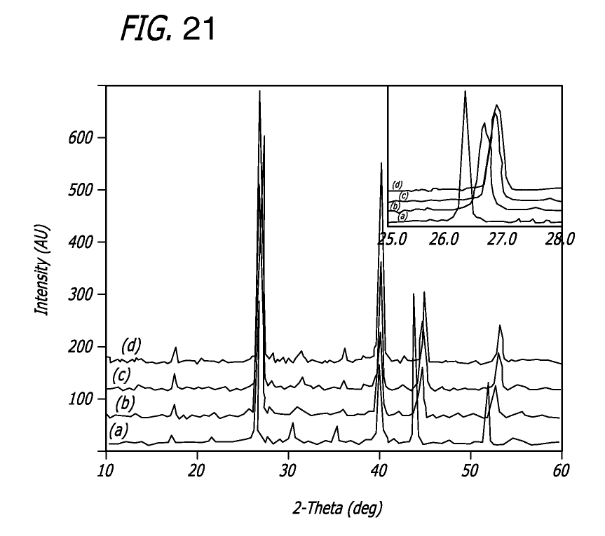

FIG. 21 shows the first and second CV scans for (A) Cu—Se, (B) Cu—In—Se, (C) Cu—Ga—Se and (D) Cu—In—Ga—Se baths, taken consecutively. The appearance of peaks in the CV figures indicates a redox reaction as occurring at the electrode, either in solution or on the surface. The CV plots are shown with cathodic current represented in the positive direction; therefore positive-going peaks represent reduction processes. The CV scans for each system are very similar in appearance, consisting of an initial current rise at ˜0 V, with a very sharp and strong peak, peak A, at ˜−0.15 V for Cu—Se or at ˜−0.35 V for the other systems. This is followed, except for the Cu-In-Se system, by a large reduction peak, peak B, which begins to grow at ˜−0.4V and reaches maximum at ˜−0.6 ˜−0.65 V. In the Cu—In—Se system only a very weak peak B, centered at ˜−0.75 V, is observed. The sharpness of peaks A and B indicate that these processes are related to the electrode surface. The rise in current at −0.8V in all plots, is due to the beginning of the hydrogen evolution reaction.

On the second, and all subsequent scans, peak A is absent in each system, as has been observed by Oliveira et al. For the Cu—Se, Cu—Ga—Se and Cu—In—Ga—Se baths, peak B remains similar on the second scan. For Cu—In—Se, however, peak B becomes more intense on the second scan and is shifted to -˜−0.6 V, though sometimes this peak has been observed at >−0.7 V. New peaks are also observed for the Cu—In—Se bath at −0.12 V and −0.25 V on the subsequent scan.

The position of peak A was found to be dependent on bath [Ga³⁺] or [In³⁺], shifting to negative potentials with increasing concentrations, and stabilizing at ˜−0.35 V at ˜2 mM for either species. With decreasing [In³⁺] in the Cu—In—Se bath, the intensity of peak B on the first CV scan was found to increase, with respect to peak A, while increasing [In³⁺] in the Cu—In—Ga—Se bath results in a decrease in peak B intensity.

The composition plots for each of these systems show similar behavior. All films grown at −0.1 V were dark and powdery and contain Cu and Se at a ratio of ˜45:˜55. GIXRD confirms that films grown at this potential consist of Cu₃Se₂ (JCPDS 47-1745), though for the Cu—Se system a mixture of Cu₃Se₂ and CuSe (JCPDS 26-0556) was observed. The discrepancy in composition and detected phases may be due to the presence of amorphous Se and other amorphous copper selenides in the films. For Cu—Se deposition at potentials <−0.1, at potentials more negative than peak A, films were dark and powdery with composition of 30 at % Cu and 70 at % Se. GIXRD indicated a conversion from Cu₃Se₂ to CuSe. Below −0.4V, coinciding with the start of peak B, gel-like films that did not adhere to the Mo substrate were obtained.

Deposition from the Cu—In—Se and Cu—Ga—Se baths at −0.2-−0.3 V, coinciding with the start of peak A, shows a change in the Cu and Se compositions, to 30 at % Cu and 65 at % Se, and uptake of In and Ga, −10 at % for both, respectively. For Cu—Ga—Se, GIXRD showed a conversion between Cu₃Se₂ to CuGaSe₂ (JCPDS 35-1100) at −0.2-−0.3 V. At more negative potentials, GIXRD and compositions remain reasonably constant, though some variation is observed at −0.6 V. CuGaSe₂ films deposited at −0.3 V and below were consistently dark and powdery. For Cu—In—Se, at −0.4 V, coinciding with the back edge of peak A, a significant increase in In levels is observed, to >20 at %, which is complemented by a decrease in deposited Cu, to <30%. At more negative potentials, a general slow increase in In and slow decrease in Cu is observed. GIXRD shows conversion of Cu₃Se₂ to a CuInSe₂ structure at −0.3 V, similar to the as-deposited film in FIG. 10. The Cu—In—Ga—Se bath shows similar features to the other three, with a change in Cu and Se compositions, to 30 at % Cu and 60 at % Se, and uptake of ˜8 at % Ga at −0.2 V. Like CuGaSe₂, the Ga composition remains near constant at potentials <−0.3 V. At −0.4 V, again corresponding to the back edge of peak A, an increase in In, to −20 at %, is observed with a corresponding decrease in Cu, to ˜25 at %. At more negative potentials, the composition of the Cu(In,Ga)Se₂ films remains constant. GIXRD showed conversion of Cu₃Se₂ to a CuInSe₂/Cu(In,Ga)Se₂ structure at −0.3 V.

With consideration of the CV, composition and GIXRD data, a preliminary mechanism for CuInSe₂ and Cu(In,Ga)Se₂ film growth can be proposed. In the initial stages of growth, the predominant deposited phase is Cu₃Se₂ and accounts for the current observed in the early periods of the CV plots. Peak A is proposed to be due to the reduction of Cu₃Se₂ to Cu₂₋ₓSe, or similar copper selenides and Se²⁻. At a bath pH of ˜2.5, H₂Se is the likely phase of dissolved Se²⁻. The liberated H₂Se will react with In³⁺ (aq) forming In₂Se₃, which, due to a favorable free energy of formation will rapidly assimilate into the growing CuInSe₂ film through reaction with Cu₂₋ₓSe. CV peak B, sometimes beginning as high as −0.4 V, is assigned to the reduction of Cu₂₋ₓSe to Cu and H₂Se. The H₂Se again will react with In³⁺ (aq) to form In₂Se₃ and, subsequently, CuInSe₂ through reaction with copper selenide. The Cu will likely generate further copper selenide by reaction with H₂Se or other Se species. In the Cu—Se system, films could not be deposited below −0.4 V, likely due to this reduction of Cu₂₋ₓSe. The appearance of the peak B is also related to bath [In³⁺]. At higher [In³⁺], a greater proportion of In₂Se₃ will be formed at −0.4 V, which in turn will react with a greater proportion of Cu₂₋Se and, therefore, a decrease in the −0.6 V peak is expected. On the subsequent scan, peak A is no longer observed, likely due to no Cu₃Se₂ remaining in the film or being deposited due to changes in the properties of the coated electrode. Peak B on the subsequent scan is assigned to the reduction of the growing film, which was confirmed from CV scans of as-deposited CuInSe₂ and Cu(In,Ga)Se₂ films in buffered LiCl solutions.

The inclusion of Ga into the growing films may occur via a similar mechanism to In uptake, via the formation and assimilation of Ga₂Se₃. However, the Ga profiles of the CuGaSe₂ and Cu(In,Ga)Se₂ systems show an uptake at −0.2-−0.3V, which remains at constant levels to negative potentials, with no clear coincidental features in the CV data. If In and Ga are incorporated into the growing films by the same mechanism, then the increase in In uptake at −0.4 V, due to generation of H₂Se, would be mirrored by Ga.

These observations, coupled with previously observed pH effects, suggest that Ga is deposited by another mechanism, possibly via limited precipitation of Ga(OH)₃ by reaction with OH— ions generated by the H₂ formation reaction. The composition profile of In for the CuInSe₂ and Cu(In,Ga)Se₂ systems shows similar behavior to Ga, before the observed increase at ˜−0.4 V. This indicates that some degree of In is also deposited as In(OH)₃ as a secondary mechanism. However, conversion of hydroxides and incorporation of the metals into the Cu(In,Ga)Se₂ structure has been confirmed following selenization of ED Cu(In,Ga)Se₂ in H₂Se, as discussed earlier for FIG. 9b.

### Sulphurization of Electrodeposited Thin Films

Improvements in film quality and device performance are expected with optimization of post-deposition treatments. Sulfur incorporation is one approach to increase the open-circuit voltage of the CuInSe₂-based devices, by widening the band gap of the absorber. For this reason, sulfurization of electrodeposited thin films is an attractive low-cost combination for processing high efficiency photovoltaic devices.

Thin films are deposited using conditions described above onto Mo electrodes from low concentration aqueous baths containing CuCl₂, InCl₃, and H₂SeO₃ for CuInSe₂. For electrodeposition of Cu(In,Ga)Se₂ films, GaCl₃ was added to the bath. Electrodeposited thin films exhibit low crystallinity and for device processing, require recrystallization by annealing at high temperature in Se— or S-containing atmospheres. Selenization in H₂Se/Ar and sulfurization in H₂S/Ar of electrodeposited thin films were performed in a laminar flow thermal chemical vapor deposition reactor at atmospheric pressure previously described. Electrodeposited Cu(In,Ga)Se₂ films were selenized in 0.35% H₂Se/Ar at 450° C. to 550° C. for 20-30 min. For comparison, some films were selenized for 30 min at 525° C. in Se-vapor in a PVD system, with Se source temperature at 250° C. Sulfurization of CuInSe₂-based films was performed in 0.35% H₂S/Ar at 550° C. for 15-45 min. The temperature, time and H₂Se/H₂S concentrations were used to control the treatment of the electrodeposited CuInSe₂-based films.

FIG. 10 illustrates typical XRD patterns of ED Cu(In,Ga)Se₂ films (a) as-deposited, (b) after selenization in Se vapor and (c) in H₂Se/Ar at 500° C. for 30 min. The inset shows clearly the shift of the 112 peak towards higher angles with the incorporation of Ga.

More particularly, FIG. 10 shows XRD patterns of Cu(In,Ga)Se₂ films, as-deposited, following selenization at 450° C. for 20 minutes in 0.35% H₂Se/Ar, and following selenization in Se-vapor at 500° C. for 20 minutes. The XRD pattern of the H₂Se-selenized film shows sharp and well defined peaks, indicating recrystallization of the film, with approximately random orientation. The expected shift of the (112) reflection, (FIG. 10 inset) with the addition of Ga to the CuInSe₂ structure is observed for the H₂Se-selenized film and is consistent with a film stoichiometry of CuIn_{0.76}Ga_{0.23}Se_{2.01}. No Ga segregation is observed and EDS results confirm the complete removal of O from the film, initially ˜17 at %, and only a minor, <1%, loss of Se, is observed, making the film slightly Cu-rich, Cu/III=1.01. In contrast, preliminary selenization treatments of electrodeposited Cu(In,Ga)Se₂ films in Se vapor resulted in incomplete recrystallization and severe cracking of the films. EDS results showed significant loss of Se, but with little change in the composition of the metals or the O content. XRD analysis of the Se-selenized film (FIG. 10 inset) confirmed the formation of CuInSe₂ (112), indicating Ga was not incorporated into the chalcopyrite structure and is likely present in an amorphous phase, possibly Ga oxide/hydroxide, which may be expected as the Ga³⁺+ions originated from an aqueous solution. The results suggest that selenization of Cu(In,Ga)Se₂ films in H₂Se, results in conversion of these oxides/hydroxides, possibly due to reaction with H₂ formed on cracking of the H₂Se during treatment, and assimilates the Ga into the chalcopyrite structure. This does not occur with treatment in Se-vapor.

The incorporation of sulfur into the chalcopyrite lattice was found to be rather complex, with difficulty in achieving a single phase film. More particularly, FIG. 22 shows XRD patterns of Cu-rich CuInSe₂ films, (a) after annealing in Ar/O₂ at 550° C. for 30 min and sulfurization at 550° C. for (b) 15 min, (c) 30 min and (d) 45 min in 0.35% H₂S/Ar. The XRD pattern of the CuInSe₂ based films shows sharp and well defined peaks, indicating recrystallization of the film, with approximately random orientation. It also shows the characteristic shift of the peaks towards higher angles due to the substitution of sulfur for selenium. The longer the reaction time the larger the substitution of Se for S, EDS results showed a substitution of S/VI=0.37, 0.54, and 0.58 for 15, 30 and 45 min, respectively. The incorporation of sulfur into the film primarily depends on the reaction time, which is facilitated with Cu/In ratio>1, forming a single phase CuIn(Se,S)₂ with no cracking observed. When Cu/In<1, the formation of a double phase and cracking is always observed, forming a CuInSe₂/CuIn(Se,S)₂ bilayer structure. The two phases are easily discerned from the XRD data, with the primary CuInSe₂ reflections split into doublets (not shown here).

Preliminary results of sulfurization experiments indicate films with composition Cu/III<l show similar behavior to that observed for CuInSe₂ films, with the formation of a bilayer structure with cracking.

### Assumptions of Technical Disclosure

Unless otherwise indicated, all numbers expressing quantities of ingredients, properties such as molecular weight, reaction conditions, and so forth used in the specification and claims are to be understood as being modified in all instances by the term “about” or “approximately.” Accordingly, unless indicated to the contrary, the numerical parameters set forth in the following specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contain certain errors necessarily resulting from the standard deviation found in their respective testing measurements.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g. “such as”) provided herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments of this invention are described herein, including the best mode known to the inventors for carrying out the invention. Of course, variations on those embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Furthermore, numerous references have been made to patents and printed publications throughout this specification. Each of the above cited references and printed publications are individually incorporated by reference herein in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

What is claimed:

1. A method for creating an electrodeposited film upon a substrate comprising the steps of:
providing a buffered aqueous solution containing Cu, In and Se;
providing an electrodeposition set-up in the buffered aqueous solution;
placing the substrate in the buffered aqueous solution and performing deposition upon the substrate via the electrode electrodeposition set-up; and
performing selenization upon the substrate in H₂Se/Ar.

2. The method of creating an electrodeposited film upon a substrate according to claim 1 wherein the step of performing selenization upon the substrate in H₂Se/Ar is performed at 450° C. for 20 minutes in 0.35% H₂Se/Ar.

3. The method of creating an electrodeposited film upon a substrate according to claim 1 wherein said buffered aqueous solution containing Cu, In and Se comprises CuCl₂, InCl₃ and H₂SeO₃.

4. The method of creating an electrodeposited film upon a substrate according to claim 1 wherein the electrodeposition set-up is a three-electrode electrodeposition set-up comprising a Mo electrode, a Pt mesh counter-electrode and a saturated calomel electrode reference electrode.

5. The method of creating an electrodeposited film upon a substrate according to claim 1 further comprising the step of performing selenization upon the substrate in Se-vapor.

6. The method of creating an electrodeposited film upon a substrate according to claim 5 further comprising the step of performing selenization upon the substrate at 500° C. for 30 minutes in Se-vapor.

7. The method of creating an electrodeposited film upon a substrate according to claim 1 wherein said buffered aqueous solution containing Cu, In and Se further comprises Ga.

8. The method of creating an electrodeposited film upon a substrate according to claim 7 wherein the step of performing selenization upon the substrate in H₂Se/Ar is performed at 450° C. for 20 minutes in 0.35% H₂Se/Ar.

9. The method of creating an electrodeposited film upon a substrate according to claim 7 wherein said buffered aqueous solution containing Cu, In, Ga and Se comprises CuCl₂, InCl₃, GaCl₃ and H₂SeO₃.

10. The method of creating an electrodeposited film upon a substrate according to claim 7 wherein the electrodeposition set-up is a three-electrode electrodeposition set-up comprising a Mo electrode, a Pt mesh counter-electrode and a saturated calomel electrode reference electrode.

11. The method of creating an electrodeposited film upon a substrate according to claim 7 further comprising the step of performing selenization upon the substrate in Se-vapor.

12. The method of creating an electrodeposited film upon a substrate according to claim 11 further comprising the step of performing selenization upon the substrate at 500° C. for 30 minutes in Se-vapor.

13. A photovoltaic device produced according to the method of claim 1, wherein the photovoltaic device has a conversion efficiency of at least 19%.

14. A photovoltaic device produced according to the method of claim 7, wherein the photovoltaic device has a conversion efficiency of at least 19%.

15. A method for creating an electrodeposited film upon a substrate comprising the steps of:
providing a buffered aqueous solution containing Cu, In and Se;
providing an electrodeposition set-up in the buffered aqueous solution;
placing the substrate in the buffered aqueous solution and performing deposition upon the substrate via the electrode electrodeposition set-up; and
performing selenization upon the substrate in Se-vapor.

16. The method of creating an electrodeposited film upon a substrate according to claim 15 wherein the step of performing selenization upon the substrate in Se-vapor is performed at 500° C. for 30 minutes in 0.35% H₂Se/Ar.

17. The method of creating an electrodeposited film upon a substrate according to claim 15 wherein said buffered aqueous solution containing Cu, In and Se comprises CuCl₂, InCl₃ and H₂SeO₃.

18. The method of creating an electrodeposited film upon a substrate according to claim 15 wherein the electrodeposition set-up is a three-electrode electrodeposition set-up comprising a Mo electrode, a Pt mesh counter-electrode and a saturated calomel electrode reference electrode.

19. The method of creating an electrodeposited film upon a substrate according to claim 15 wherein said buffered aqueous solution containing Cu, In and Se further comprises Ga.

20. The method of creating an electrodeposited film upon a substrate according to claim 19 wherein the step of performing selenization upon the substrate in Se-vapor is performed at 500° C. for 30 minutes.

21. The method of creating an electrodeposited film upon a substrate according to claim 19 wherein said buffered aqueous solution containing Cu, In, Ga and Se comprises CuCl₂, InCl₃, GaCl₃ and H₂SeO₃.

22. The method of creating an electrodeposited film upon a substrate according to claim 19 wherein the electrodeposition set-up is a three-electrode electrodeposition set-up comprising a Mo electrode, a Pt mesh counter-electrode and a saturated calomel electrode reference electrode.

23. A photovoltaic device produced according to the method of claim 15 wherein the photovoltaic device has a conversion efficiency of at least 19%.

24. A photovoltaic device produced according to the method of claim 19, wherein the photovoltaic device has a conversion efficiency of at least 19%.

25. A method for creating an electrodeposited film upon a substrate comprising the steps of:
providing a buffered aqueous solution containing Cu, In and Se;
providing an electrodeposition set-up in the buffered aqueous solution;
placing the substrate in the buffered aqueous solution and performing deposition upon the substrate via the electrode electrodeposition set-up; and
performing sulfurization upon the substrate in H₂S/Ar.

26. The method of creating an electrodeposited film upon a substrate according to claim 25 wherein the step of performing sulfurization upon the substrate in H₂S/Ar is performed at 550° C. for 30 minutes in H₂S/Ar.

27. The method of creating an electrodeposited film upon a substrate according to claim 25 wherein said buffered aqueous solution containing Cu, In and Se comprises CuCl₂, InCl₃ and H₂SeO₃.

28. The method of creating an electrodeposited film upon a substrate according to claim 25 wherein the electrodeposition set-up is a three-electrode electrodeposition set-up comprising a Mo electrode, a Pt mesh counter-electrode and a saturated calomel electrode reference electrode.

29. The method of creating an electrodeposited film upon a substrate according to claim 25 wherein said buffered aqueous solution containing Cu, In and Se further comprises Ga.

30. The method of creating an electrodeposited film upon a substrate according to claim 29 wherein the step of performing sulfurization upon the substrate in H₂S/Ar is performed at 550° C. for 30 minutes in H₂S/Ar.

31. The method of creating an electrodeposited film upon a substrate according to claim 29 wherein said buffered aqueous solution containing Cu, In, Ga and Se comprises CuCl₂, InCl₃, GaCl₃ and H₂SeO₃.

32. The method of creating an electrodeposited film upon a substrate according to claim 29 wherein the electrodeposition set-up is a three-electrode electrodeposition set-up comprising a Mo electrode, a Pt mesh counter-electrode and a saturated calomel electrode reference electrode.

33. A photovoltaic device produced according to the method of claim 25, wherein the photovoltaic device has a conversion efficiency of at least 19%.

34. A photovoltaic device produced according to the method of claim 29, wherein the photovoltaic device has a conversion efficiency of at least 19%.
